(19) United States
(12) Patent Application Publication
(10) Pub. No.: US 2015/0255554 A1
(43) Pub. Date: Sep. 10, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Hiroshi ITOKAWA, Ooita Ooita (JP)

(21) Appl. No.: 14/634,698

(22) Filed: Feb. 27, 2015

Related U.S. Application Data
(60) Provisional application No. 61/950,511, filed on Mar. 10, 2014.

(51) Int. Cl. H01L 29/423; H01L 21/28; H01L 27/115

(52) U.S. Cl. CPC H01L 29/42332; H01L 27/11524; H01L 21/28273

(57) ABSTRACT

A semiconductor device includes a semiconductor substrate, a first insulation film disposed on the semiconductor substrate, a film including silicon disposed over the first insulation film, a second insulation film disposed on the film, and a plurality of metal dots disposed on the second insulation film, a semiconductor film selectively formed on the plurality of metal dots, and a high dielectric constant insulation film disposed on the semiconductor film and the second insulation film.

### CROSS-REFERENCE TO RELATED APPLICATION

This application is based upon and claims the benefit of priority from U.S. Provisional Patent Application No. 61/950,511, filed Mar. 10, 2014, the entire contents of which are incorporated herein by reference.

### BACKGROUND

NAND-type flash memory is a popular form of non-volatile memory used in used in main memory, memory cards, USB flash drives, solid-state drives, and similar products. NAND-type flash memory stores memory by storing charges in the floating gate electrodes of floating gate transistors. NAND-type flash memory has an architecture where the memory transistors are connected in series, which results in increased memory storage density compared to other memories, such as NOR-type flash memory. To further increase the memory storage density, the size of components and thicknesses of layers must be further reduced. However, when miniaturizing a NAND-type flash memory device, a problem of holding a charge in a floating gate electrode occurs.

Therefore there is a need for an improved NAND-type flash memory device that allows further increases in the memory storage density thereof.

### BRIEF DESCRIPTION OF THE DRAWINGS

FIG. 1 is a circuit diagram of a memory cell array of a NAND-type flash memory device according to a first embodiment.

FIG. 2 is a schematic plan view of a portion of a memory cell region according to the first embodiment.

FIG. 3A is a schematic cross-sectional view taken along a line A-A of FIG. 2, and FIG. 3B is a schematic cross-sectional view taken along a line B-B of FIG. 2.

FIG. 4 is a cross-sectional view taken along the line B-B of FIG. 2 during manufacture.

FIG. 5 is a cross-sectional view taken along the line B-B of FIG. 2 during manufacture.

FIG. 6 is an enlarged cross-sectional view of a main part taken along the line B-B of FIG. 2 during manufacture.

FIG. 7 is an enlarged cross-sectional view of a main part taken along the line B-B of FIG. 2 during manufacture.

FIG. 8 is an enlarged cross-sectional view of a main part taken along the line B-B of FIG. 2 during manufacture.

FIG. 9 is an enlarged cross-sectional view of a main part taken along the line B-B of FIG. 2 during manufacture.

FIG. 10 is an enlarged cross-sectional view of a main part taken along the line B-B of FIG. 2 during manufacture.

FIG. 11 is a cross-sectional view taken along the line B-B of FIG. 2 during manufacture.

FIG. 12 is a band gap view which illustrates an operation of an NAND-type flash memory device, according to the first embodiment.

FIG. 13 is an enlarged cross-sectional view of a main part taken along the line B-B of FIG. 2 during manufacture, according to a comparative example 1.

FIG. 14 is an enlarged cross-sectional view of a main part taken along the line B-B of FIG. 2 during manufacture, according to comparative example 1.

FIG. 15 is the enlarged cross-sectional view of a main part taken along the line B-B of FIG. 2 during manufacture, according to comparative example 1.

FIG. 16 is an enlarged cross-sectional view of a main part taken along the line B-B of FIG. 2 during manufacture, according to a comparative example 1.

FIG. 17 is a characteristic view which shows a relationship between a write voltage/an erase voltage and a threshold voltage.

FIG. 18 is an enlarged cross-sectional view of a main part taken along the line B-B of FIG. 2 during manufacture, according to comparative example 2.

FIG. 19 is an enlarged cross-sectional view of a main part taken along the line B-B of FIG. 2 during manufacture, according to comparative example 2.

FIG. 20 is an enlarged cross-sectional view of a main part taken along the line B-B of FIG. 2 during manufacture, according to comparative example 2.

FIG. 21 is an enlarged cross-sectional view of a main part taken along the line B-B of FIG. 2 during manufacture, according to comparative example 2.

### DETAILED DESCRIPTION

In order to solve the problem of holding a charge in a floating gate electrode when the dimensions of a NAND-type flash memory elements are further reduced, a configuration is proposed by which the charge holding characteristics of the floating gate electrode are improved by forming the top of the floating gate electrode with a metal and increasing the band gap between the floating gate electrode and an insulation film which is interposed between the floating gate electrode and a control gate electrode.

A semiconductor device according to an embodiment includes a semiconductor substrate, a first insulation film disposed on the semiconductor substrate, a film including silicon disposed over the first insulation film, a second insulation film disposed on the film, and a plurality of metal dots disposed on the second insulation film, a semiconductor film selectively formed on the plurality of metal dots, and a high dielectric constant insulation film disposed on the semiconductor film and the second insulation film.

Hereinafter, a plurality of embodiments will be described referring to the drawings. In each embodiment, like reference numerals refer to like elements, and thus repeated description of the same elements will not be repeated. However, the drawings are schematic, so that a relationship between thickness and planar size, a ratio of thickness of each layer, and the like may be different from actual devices.

### First Embodiment

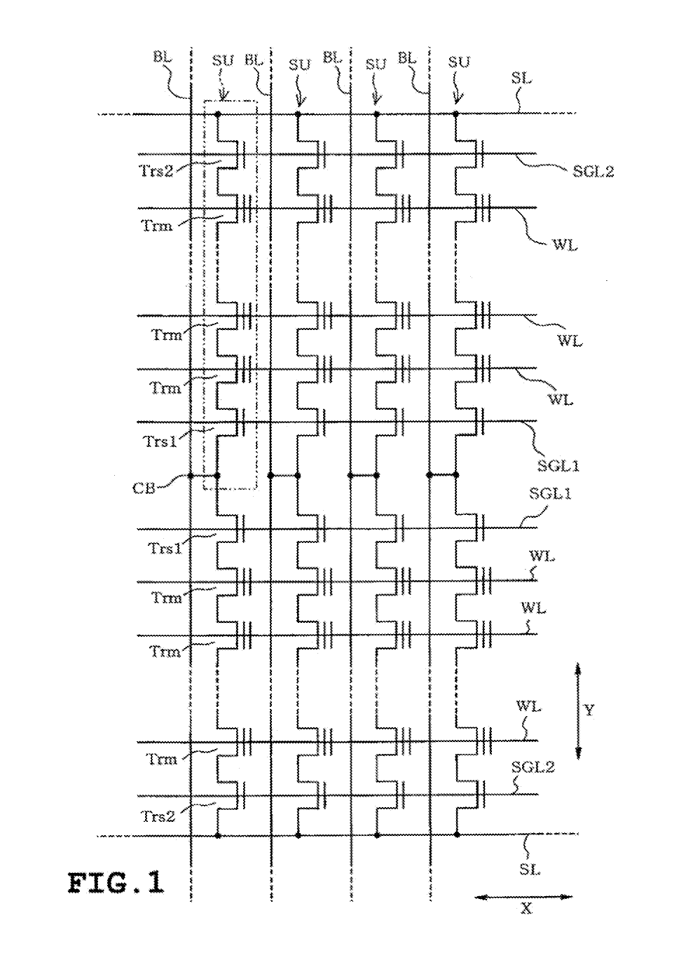

FIG. 1 is a circuit diagram of a portion of a memory cell array formed in a memory cell region of a NAND-type flash memory device of a first embodiment. As shown in FIG. 1, a NAND cell unit SU includes two selection gate transistors Trs1 and Trs2 and a plurality (for example, 64) of memory cell transistors Trm connected in series. The memory cell transistors Trm are disposed between the selection gate transistors Trs1 and Trs2. Adjacent memory cell transistors Trm in the NAND cell unit SU share a source/drain region.

The memory cell transistors Trm of adjacent NAND cell units SU are also spaced in an X direction of FIG. 1 and are connected at the gates thereof by word lines WL. The spaced locations of the memory cell transistors in the individual NAND cell units SU in the Y direction, and the spaced relationship of the NAND cell units SU in the X direction, form a matrix of memory cell transistors Trm in the X-Y plane. The selection gate transistors Trs1 of the individual NAND cell units SU are spaced in the X direction of FIG. 1 and are connected in common to a selection gate line SGL1. The selection gate transistors Trs2 of the individual NAND cell units SU are spaced in the X direction of FIG. 1 are connected in common to a selection gate line SGL2. A bit line contact CB is connected to a drain region of the selection gate transistors Trs1. The bit line contact CB is connected to a bit line BL extending in a Y direction (a gate length direction, corresponding to a bit line direction) which is orthogonal to the X direction of FIG. 1. Additionally, the selection gate transistors Trs2 are connected to a source line SL extending in the X direction of FIG. 1 through a source region.

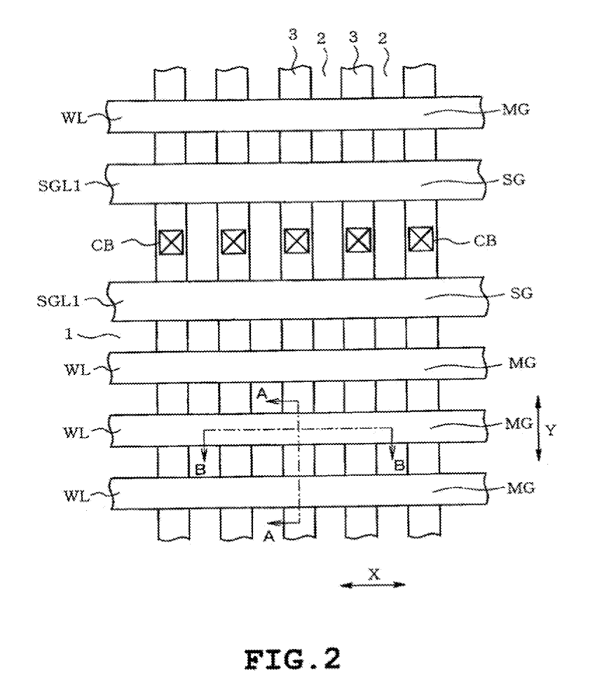

FIG. 2 is a plan view showing a layout pattern of a portion of a memory cell region and an extraction region of a word line. A plurality of shallow trenches forming isolations (STI) 2 extending in the Y direction of FIG. 2 act as element isolation regions and are formed at predetermined intervals (spacing) in the X direction into the surface of, or into a layer formed on, a silicon substrate 1. Accordingly, a plurality of active regions 3 extending in the Y direction are separately formed between the trenches at predetermined intervals in the X direction. The word lines WL of the memory cell transistors extend orthogonally to the direction of extension of the active regions 3, i.e., they extend in the X direction, and at predetermined intervals in the Y direction.

In addition, a pair of selection gate lines SGL1 connecting the selection gate transistors extend across the NAND memory cell units SU (FIG. 1) along the X direction. Bit line contacts CB are formed in the active regions 3 between a pair of selection gate lines SGL1. A gate electrode MG of a memory cell transistor is formed where the active regions 3 intersect the word lines WL. A gate electrode SG for the selection gate transistors is formed where the active regions 3 intersect the selection gate lines SGL1.

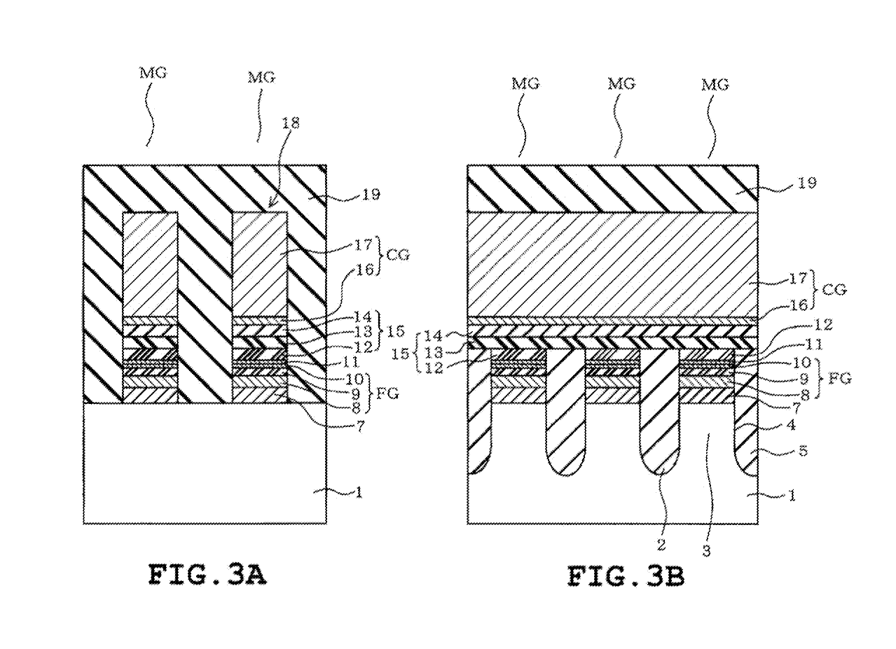

Referring to FIGS. 3A and 3B, a gate electrode of a flat cell structure in a memory cell region, according to the first embodiment, is described. FIG. 3A is a schematic view showing a cross-section taken along a line A-A of FIG. 2 (i.e., the bit line direction or Y direction), and FIG. 3B is a schematic view showing a cross-section taken along a line B-B of FIG. 2 (i.e., the word line direction or X direction).

As shown in FIG. 3B, a plurality of element isolation trenches 4 are separated from each other in the X-direction and extend inwardly of the upper surface of the silicon substrate 1. The area of the substrate 1 remaining after the element isolation trenches are formed therein become the active regions 3, which are spaced from one another in the X direction of FIG. 3B, and are electrically isolated from each other by the element isolation trenches 4. An element isolation insulation film 5 is formed into the element isolation trenches 4 to form the element isolation region (STI) 2.

A tunnel insulation film (a first insulation film) 7 is formed on the silicon substrate 1. The tunnel insulation film 7 is made of, for example, silicon oxide (SiO₂), and a thickness of the film is, for example, about from 6 nm to 7 nm. The tunnel insulation film 7 generally has an insulating property. However, when a predetermined voltage in a range of drive voltages for a NAND-type flash memory device is applied, the tunnel insulation film 7 allows a tunneling current to flow therein. A source/drain region (not illustrated) is formed at both sides of the gate electrode MG in a surface layer portion of the silicon substrate 1.

On the tunnel insulation film 7, a silicon film 8 made of polycrystalline silicon is formed. A thickness of the silicon film 8 is, for example, about 5 nm. An insulation film (a second insulation film, an IFD film) 9 made of, for example, silicon nitride (Si₃N₄) or aluminum oxide (Al₂O₃), is formed on the silicon film 8. A thickness of the insulation film 9 is, for example, about 2 nm.

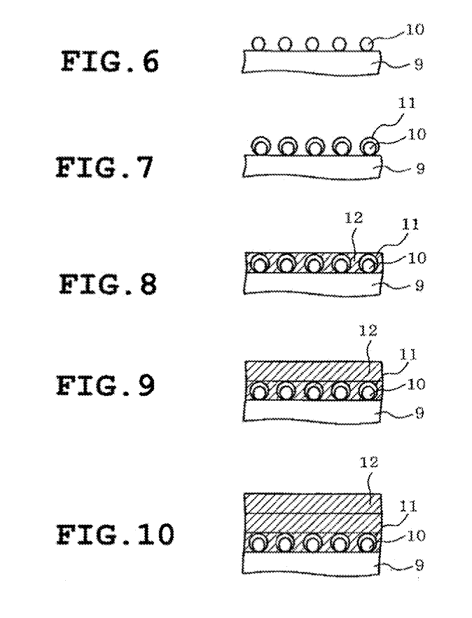

A metal film 10 made of, for example, ruthenium (Ru), is formed on the insulation film 9. A thickness of the metal film 10 is, for example, about 1 nm or less. The metal film 10 is formed in a dot shape (refer to FIG. 6). A semiconductor film 11 which is mostly silicon is selectively formed on the metal film 10 (refer to FIG. 7).

A hafnium oxide film (first hafnium oxide film) 12, which is mostly hafnium oxide (HfO₂), is formed as a high dielectric constant (Hi-k) insulation film on the insulation film 9 and the semiconductor film 11 (refer to FIGS. 8, 9, and 10 for detail illustrating how the hafnium oxide film 12 is formed on insulation film 9 and semiconductor film 11). Further details for the metal film 10, the semiconductor film 11, and the hafnium oxide film 12 will be described below.

A floating gate electrode film FG includes the silicon film 8, the insulation film 9, and the metal film 10. On the silicon substrate 1 and tunnel insulation film 7, a plurality of the floating gate electrode films FG are formed and arranged in a matrix shape in an X direction and a Y direction. The element isolation insulation film 5 extends above the surface of the substrate 1, and thus also extends between adjacent ones of the stacks made of the floating gate electrode films FG and the hafnium oxide film 12.

A silicon oxide film 13 made of silicon oxide and a hafnium oxide film (second hafnium oxide film) 14 made of hafnium oxide are formed in this order on the hafnium oxide film 12 and the element isolation insulation film 5. The silicon oxide film 13 and the hafnium oxide film 14 extend in the X direction over adjacent hafnium oxide film 12 locations and the uppermost (furthest from the substrate 1) surface of the insulation films 5. An inter poly dielectric (IPD) film (inter-electrode insulation film, high dielectric constant insulation film) 15 is formed by the individual hafnium oxide films 12, the silicon oxide film 13, and the hafnium oxide film 14.

A barrier film 16 made of, for example, tantalum nitride (TaN), is formed on the IPD film 15. A conductive film 17 made of, for example, tungsten (W), is formed on the barrier film 16. A control gate electrode CG extending in the X direction is thus formed by the barrier film 16 and the conductive film 17.

In this configuration, a gate stack 18 extending in the X direction is formed by a top of the element isolation insulation film 5, the tunnel insulation film 7, the floating gate electrode FG, the semiconductor film 11, the IPD film 15, and the control gate electrode CG. A plurality of gate stacks 18 are provided on the silicon substrate 1. An interlayer insulation film 19 made of, for example, silicon oxide, is formed between the gate stacks 18 and/or above the gate stack 18. Upper-layer wiring including a bit line is formed on the interlayer insulation film 19.

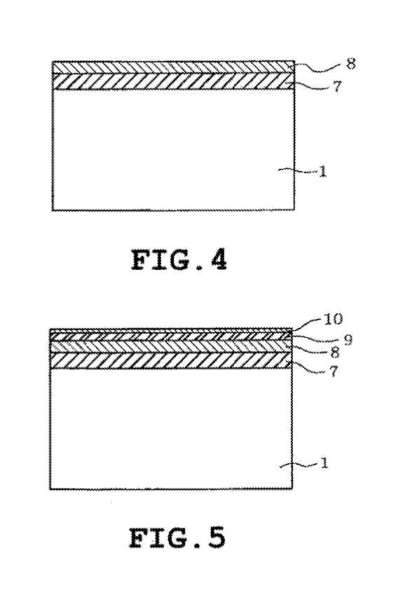

Next, a method of manufacturing the NAND-type flash memory device according to one embodiment will be described referring to FIGS. 4 to 11. FIGS. 4 to 11 schematically show manufacturing steps of forming the memory structure having the same cross-sectional view shown in FIG. 3B.

First, as shown in FIG. 4, the tunnel insulation film 7 made of, for example, silicon oxide, is formed on the silicon substrate 1. Next, the silicon film 8 made of polycrystalline silicon is formed on the tunnel insulation film 7.

Next, as shown in FIG. 5, the insulation film 9 made of, for example, silicon nitride, is formed on the silicon film 8. Subsequently, the metal film (ruthenium film) 10 is formed on the insulation film 9 by depositing, for example, ruthenium, using a sputtering (physical vapor deposition) process. In this case, the metal film 10 is substantially about 1 nm in thickness, and results in a dot shape as shown in FIG. 6 or other non-continuous structure. In addition, dots of the metal film 10 have a bottom bonded to an upper surface of the insulation film 9.

Afterwards, as shown in FIG. 7, the semiconductor film 11, which is mostly silicon, is selectively formed on the metal film 10 in a dot shape. Accordingly, the semiconductor film 11, e.g., a RuSiₓ film, is formed on a surface of the metal film 10 in a dot shape. In this case, the semiconductor film 11 is selectively formed on the ruthenium dots using, for example, an ultra high vacuum (UHV)-chemical vapor deposition (CVD) method. As a process condition of the UHV-CVD method, a process temperature is set to, for example, about 400° C. to about 600° C. and a pressure is set to, for example, 10 mTorr or less, and a silicon source, such as SiH₄ or Si₂H₆ gas, is used as the reaction gas. By using the UHV-CVD method, it is possible to selectively form the semiconductor film 11 using a difference of nuclear growth time (incubation time) for Si formation on the ruthenium film as compared to the underlying insulation film 9.

Moreover, when setting the process temperature of the UHV-CVD method to, for example, about from 500° C. to 600° C., the entire dot of the metal film 10 is converted to a (RuSiₓ) compound. When the process temperature is held at about 400° C. to about 450° C., only a surface layer of the dot of the metal film 10 is converted to the (RuSiₓ) compound. Moreover, for some embodiments, the pressure can be set to, for example, 1 mTorr or less. Also, instead of SiH₄ or Si₂H₆ gas as a reaction gas, a mixture of SiH₄ gas and GeH₄ gas may be used. When adding Ge in this manner, selectivity for depositing Silicon on the ruthenium and not the insulation film 9 is further improved. Furthermore, instead of the semiconductor film 11, which is mostly silicon, the semiconductor film (RuGeₓfilm) 11, which is mostly germanium, may be selectively formed on the ruthenium dot surface. In addition, silicon may be added to the semiconductor film 11 (RuGeₓ film).

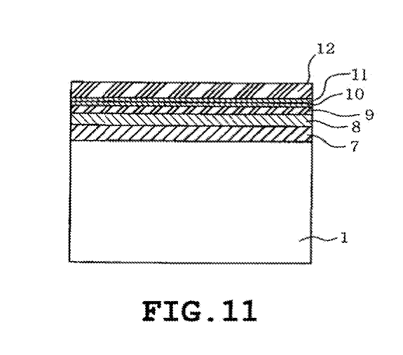

Next, as shown in FIGS. 8 to 10, the hafnium oxide film 12 is formed by depositing hafnium and oxygen using, for example, an atomic layer deposition (ALD) method. As shown in FIG. 8, the hafnium oxide film 12 of a thickness sufficient to embed the dot shaped metal film 10 and the semiconductor film 11 is formed by depositing HfOₓ in a first cycle of the ALD method. Subsequently, as shown in FIG. 9, the thickness of the hafnium oxide film 12 increases by depositing HfOₓ in a second cycle of the ALD method. Furthermore, as shown in FIG. 10, the thickness of the hafnium oxide film 12 becomes even thicker (for example, to about 5 nm) by depositing HfOₓ by performing a third or subsequent cycle of the ALD method. Accordingly, a film layer stack configuration shown in FIG. 11 is obtained. It is noted that the metal film 10 and the semiconductor film 11 are shown in a two-layer structure without the detail of the dot structure for convenience in FIG. 11.

Thereafter, as shown in FIGS. 3A and 3B, in order to form the element isolation region 2, a hard mask (not illustrated) in a line-and-space shape which extends in the Y direction is formed on the hafnium oxide film 12. Next, by performing anisotropic etching on film layer stack using the hard mask as a mask, the hafnium oxide film 12, the semiconductor film 11, the metal film 10, the insulation film 9, the silicon film 8, and the tunnel insulation film 7 are selectively removed and divided, and the element isolation trenches 4 extending in the Y direction are formed into the silicon substrate 1. Thereafter, the hard mask is stripped off, and the element isolation insulation film 5 is formed by depositing, for example, a silicon oxide film, into the trenches 4 and over the film stack, followed by an etch-back process to remove the insulation film from the location over the top of the hafnium oxide film 12. The lower portion of the element isolation insulation film 5 is embedded in the element isolation trenches 4 within the substrate 1, and the upper portion of the element isolation insulation film 5 is disposed between the adjacent thin film stacks of the tunnel insulation film 7, the silicon film 8, the insulation film 9, the metal film 10, the semiconductor film 11, and the hafnium oxide film 12.

Next, the silicon oxide film 13, the hafnium oxide film 14, the barrier film 16, and the conductive film 17 are formed in this order on the hafnium oxide film 12 and the element isolation insulation film 5. Thereafter, a hard mask in a line-and-space shape (not illustrated) extending in an X direction is formed. Then, tops of the conductive film 17, the barrier film 16, the hafnium oxide film 14, the silicon oxide film 13, the hafnium oxide film 12, the semiconductor film 11, the metal film 10, the insulation film 9, the silicon film 8 and the tunnel insulation film 7, and the element isolation insulation film 5 are selectively removed by performing anisotropic etching using the hard mask as an etch mask. Accordingly, a plurality of the gate stacks 18 extending in the X direction are formed.

In this configuration, the film stack made of the silicon film 8, the insulation film 9, and the metal film. 10 is divided in the X direction and the Y direction, and forms a plurality of the floating gate electrodes FG arranged in a matrix pattern. In addition, the IPD film 15 is formed by a stack made of the hafnium oxide film 12, the silicon oxide film 13, and the hafnium oxide film 14. Furthermore, a stack made of the barrier film 16 and the conductive film 17 is processed to be in a stripe shape extending in the X direction, and becomes the control gate electrode CG.

Next, the interlayer insulation film 19 is formed between and above the gate stacks 18 by depositing a silicon oxide film thereover and performing a planarization process such as chemical mechanical polishing. Thereafter, the upper wiring including a bit line is formed on the interlayer insulation film 19.

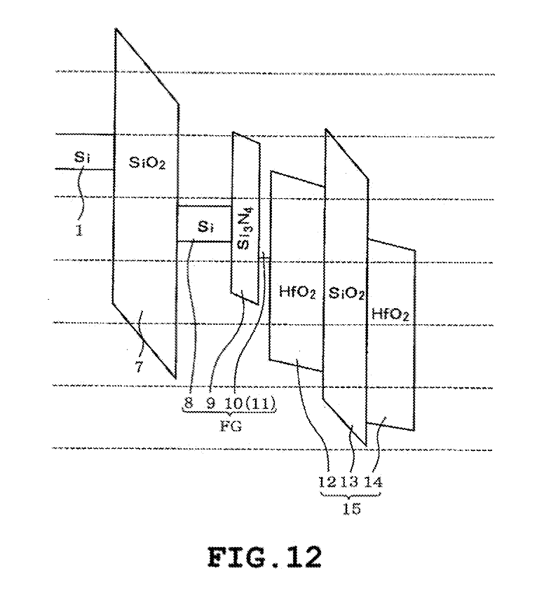

FIG. 12 is a band gap view illustrating an example of an operation of the NAND-type flash memory device of the embodiment.

According to the first embodiment, the metal film 10 is formed to be in a dot shape on the insulation film 9, and the semiconductor film 11, which is mostly silicon, is selectively formed on the metal film 10 in a dot shape, such that the metal film 10 is stable. The metal film 10 is stable because the structure of the hafnium oxide film 12 formed on the semiconductor film 11 over the metal film 10 is able to suppress diffusion of the ruthenium included in the metal film 10 into the hafnium oxide film 12. Thus, although the metal film 10 is thinly formed, it is possible to contain the metal atoms within the metal film 10 or within the metal film 10-semiconductor film 11 compound.

When it is possible to form the metal film 10 as described above, the energy level of an electron in the metal film 10 is lower than the energy level of the electron in the insulation film 9 and in the hafnium oxide film 12, such that electrons accumulate on the metal film 10. Therefore, it is possible to form a high barrier to electron exchange between the metal film 10 and the hafnium oxide film 12, such that the IPD film 15 can be thinner and the characteristic of holding a charge in the floating gate electrode FG can be improved. Furthermore, when the characteristic of holding a charge in the floating gate electrode FG can be improved, it is possible to make the tunnel insulation film 7 thinner as well. Furthermore, when the tunnel insulation film 7 and the IPD film 15 can be made thinner, it is possible to lower the write voltage (Vpgm) and an erase voltage (Vera) of the memory cells.

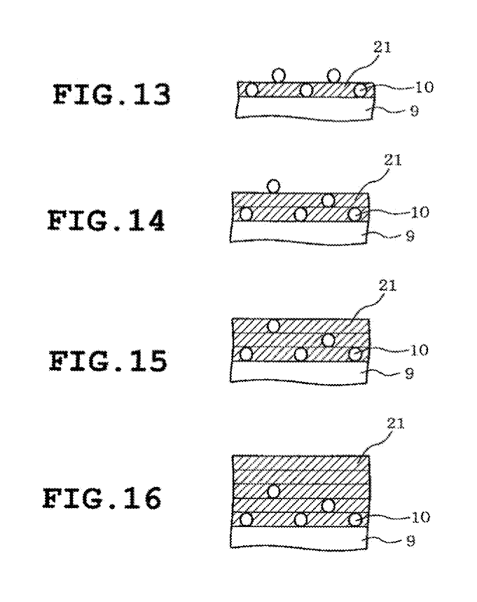

Next, a comparative example 1 will be described referring to FIGS. 13 to 16. A process of forming comparative example 1 is the same as forming the first embodiment until after forming the metal film (ruthenium film) 10 on the insulation film 9 as described in reference to FIG. 6. For the first embodiment, the semiconductor film 11 was then formed on the metal film 10 in a dot shape using, for example, the UHV-CVD method (i.e., See FIG. 7), followed by a formation of the hafnium oxide film 12 on the semiconductor film 11 and the insulating film 9. Alternatively, for comparative example 1, as shown in FIG. 13, a hafnium oxide film 21 with a thickness sufficient to embed the metal film 10 (without the presence of the semiconductor film 11) in a dot shape is formed by depositing HfOₓ in the first cycle of the ALD method.

Subsequently, as shown in FIG. 14, a thickness of the hafnium oxide film 21 is increased by depositing HfOₓ in the second cycle of the ALD method. Furthermore, as shown in FIG. 15, the thickness of the hafnium oxide film 21 is further increased by depositing HfOₓ by performing a third or subsequent cycle of the ALD method. Moreover, as shown in FIG. 16, the thickness of the hafnium oxide film 21 reaches a required thickness (for example, about 5 nm) by depositing HfOₓ by performing a fourth or subsequent cycle of the ALD method.

For comparative example 1, as shown in FIG. 13, during a process of depositing HfOₓ in the first cycle of the ALD method, problems relating to a surface segregation phenomenon of ruthenium or a diffusion of ruthenium into the hafnium oxide film 21 by auto-doping occur. Consequently, a portion of the dot shaped ruthenium layer 10 is exposed to the surface of the hafnium oxide film 21. It is known that this surface segregation phenomenon or this diffusion phenomenon can also occur when depositing HfOₓ in the second cycle and the third cycle of the ALD method as shown in FIGS. 14 and 15. As a result, ruthenium is diffused into the hafnium oxide film 21 as shown in FIG. 16 for the comparative example 1 deteriorating the insulation properties of the hafnium oxide film 21. These decreased insulation properties can result in a leakage current through the hafnium oxide film 21 as well as a reduced breakdown voltage for the hafnium oxide film 21.

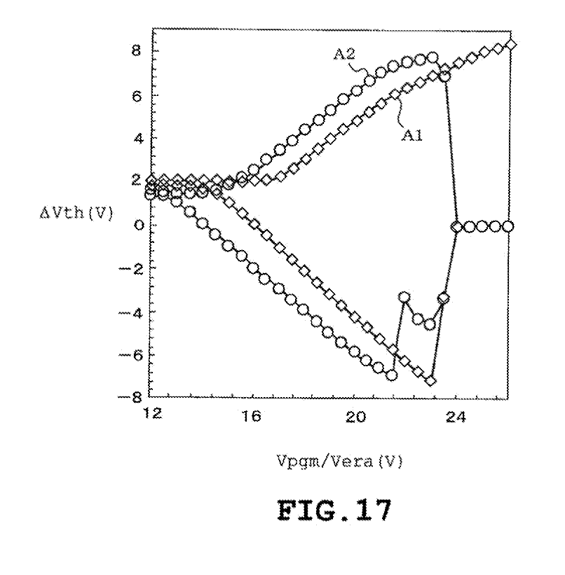

FIG. 17 is a diagram showing a result of measuring a relationship between a ratio of a write voltage to an erase voltage (Vpgm/Vera) and a threshold voltage (ΔVth) of the NAND-type flash memory device of the comparative example 1. A curve A1 plotted by squares shows a configuration in which the metal film (ruthenium film) 10 is not formed. A curve A2 plotted by circles shows a configuration in which the metal film (ruthenium film) 10 is formed according to comparative example 1. From FIG. 17, it is evident that the ratio of the write voltage to the erase voltage (Vpgm/Vera) can be lowered when the configuration of the metal film of comparative example 1 is employed, but breakdown voltage characteristics will be deteriorated.

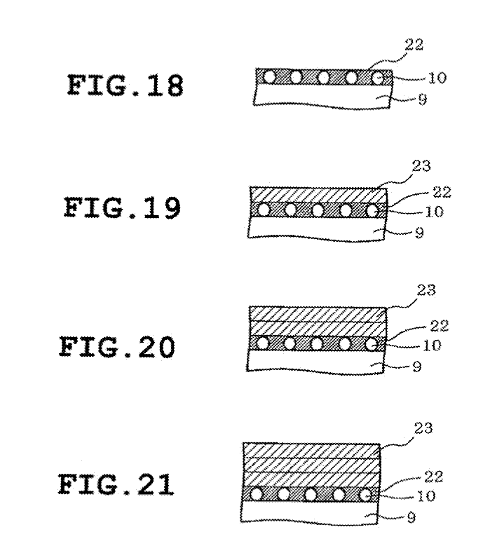

Next, a comparative example 2 as a configuration to solve the above-mentioned problem of the comparative example 1 will be described referring to FIGS. 18 to 21. A process of forming comparative example 2 is the same as forming the first embodiment until after the metal film (ruthenium film) 10 is formed on the insulation film 9 as described in reference to FIG. 6. Thereafter, as shown in FIG. 18, a cap film 22 which is made of, for example, a silicon oxide (SiO₂) or a silicon nitride (Si₃N₄), is formed on the dot shaped metal film 10. The cap film 22 suppresses the surface segregation phenomenon and the diffusion phenomenon of ruthenium observed in comparative example 1.

Thereafter, a hafnium oxide film 23 is formed on the cap film 22 using the ALD method. In this case, as shown in FIG. 19, the hafnium oxide film 23 with a thin thickness is formed on the cap film 22 by depositing HfOₓ in the first cycle of the ALD method. Subsequently, as shown in FIG. 20, a thickness of the hafnium oxide film 23 is increased by depositing HfOₓ in the second cycle of the ALD method. Furthermore, as shown in FIG. 21, the thickness of the hafnium oxide film 23 reaches a required thickness (for example, about 5 nm) by depositing HfOₓ in the third or subsequent cycle of the ALD method.

The cap film 22 formed on the metal film 10 suppresses the surface segregation phenomenon or the diffusion phenomenon of ruthenium observed for comparative example 1. Thus, the cap film 22 prevents deterioration of the insulation properties of the hafnium oxide film 23. However, it is noted that comparative example 2 has an increased stacked equivalent oxide thickness (EOT).

Where, as in the first embodiment, the semiconductor film 11, which is mostly silicon is selectively formed on the dot shaped metal film 10, the ruthenium included in the metal film 10 is suppressed from diffusing into the hafnium oxide film even if the hafnium oxide film 12 is formed on the semiconductor film 11 over the semiconductor film 11-metal film 10 combination using an ALD method. Consequently, for the first embodiment, it is possible to lower the ratio of the write voltage to the erase voltage (Vpgm/Vera) and to sufficiently increase breakdown voltage characteristics as well as further sufficiently decrease the EOT.

### The Other Embodiments

In addition to a plurality of embodiments described above, the following configurations may be adopted.

In each embodiment described above, ruthenium is used as the metal film 10; however, the embodiments are not limited to ruthenium. For example, iridium may be used or an alloy of ruthenium and iridium may be used. In addition, the IPD film 15 is configured to have stacked films of the hafnium oxide film 12, the silicon oxide film 13, and the hafnium oxide film 14; however, instead of this, the IPD film 15 may include stacked films of a hafnium oxide film, an aluminum oxide film, and a hafnium oxide film. Furthermore, the hafnium oxide film 14 of the IPD film 15 may include at least one type of gadolinium (Gd), erbium (Er), lanthanum (La), silicon (Si), and aluminum (Al). Furthermore, the hafnium oxide film 12 used as a high dielectric constant insulation film, could be replaced with other high dielectric constant insulation films.

As described above, it is possible to suppress the ruthenium included in the metal film 10 from being diffused into the hafnium oxide film 12 by the NAND-type flash memory device of the first embodiment. The lower energy level of the metal film relative to the surrounding insulation layers allows electrons to accumulate on or in the metal film and allows for a high barrier to electron movement between the metal film and into the adjacent hafnium oxide film. This high barrier allows for improved charge-holding properties for the floating gate electrode. The improved charge-holding properties of the floating gate electrode allow for thinner IPD films and tunnel films to be used resulting in increased memory storage densities. Furthermore, these thinner films in turn allow for reduced write and erase voltages improving the efficiency of the NAND-type flash memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a first insulation film disposed on the semiconductor substrate;
a film including silicon disposed over the first insulation film,
a second insulation film disposed on the film,
a plurality of metal dots disposed on the second insulation film;
a semiconductor film selectively formed on the plurality of metal dots; and
a high dielectric constant insulation film disposed on the semiconductor film and the second insulation film.

2. The semiconductor device according to claim 1, wherein
the plurality of metal dots comprise at least one of ruthenium or iridium.

3. The semiconductor device according to claim 1, wherein
the semiconductor film comprises mostly silicon.

4. The semiconductor device according to claim 3, wherein
the semiconductor film comprises germanium.

5. The semiconductor device according to claim 1, wherein
the semiconductor film comprises mostly germanium.

6. The semiconductor device according to claim 1, wherein
the second insulation film comprises a silicon nitride film or an aluminum oxide film.

7. The semiconductor device according to claim 1, wherein
the high dielectric constant insulation film comprises a stack of a first hafnium oxide film, a silicon oxide film, and a second hafnium oxide film, wherein the first hafnium oxide film is disposed on the semiconductor film.

8. The semiconductor device according to claim 7, wherein
the second hafnium oxide film comprises at least one of gadolinium, erbium, lanthanum, silicon, or aluminum.

9. The semiconductor device according to claim 7, wherein
the first hafnium oxide film is divided in a first direction and a second direction, and
the silicon oxide film and the second hafnium oxide film extend in the second direction and are divided in the first direction.

10. The semiconductor device according to claim 1,
wherein the high dielectric constant insulation film comprises a stack of a first hafnium oxide film, an aluminum oxide film, and a second hafnium oxide film, wherein the first hafnium oxide film is disposed on the semiconductor film.

11. The semiconductor device according to claim 9, further comprising:
an electrode disposed over the high dielectric constant insulation film extends in the second direction.

12. A semiconductor device comprising:
a semiconductor substrate;
a first insulation film formed on the semiconductor substrate;
a silicon film formed on the first insulation film;
a second insulation film formed on the silicon film;
a metal film comprising a plurality of metal dots formed on the second insulation film;
a semiconductor film selectively formed on the metal film;
a high dielectric constant insulation film formed on the second insulation film and the semiconductor film; and
an electrode formed on the high dielectric constant insulation film.

13. A method of manufacturing a semiconductor device, the method comprising:
forming a first insulation film on a semiconductor substrate;
forming a silicon film on the first insulation film;
forming a second insulation film on the silicon film;
forming a plurality of metal dots on the second insulation film;
selectively forming a semiconductor film on the plurality of metal dots;
forming a high dielectric constant insulation film comprising mostly hafnium on the second insulation film and the semiconductor film; and
forming an electrode on the high dielectric constant insulation film.

14. The method according to claim 13,
wherein, the semiconductor film comprises mostly silicon and the semiconductor film is formed on the plurality of metal dots using a UHV-CVD method.

15. The method according to claim 14,
wherein a process temperature of the UHV-CVD method is set to about 500° C. to about 600° C., and
entire dots of the plurality of metal dots are transformed into a metal-silicon compound.

16. The method according to claim 14,
wherein a process temperature of the UHV-CVD method is set to about 400° C. to about 450° C., and
a surface layer of the plurality of metal dots is transformed into a metal-silicon compound.

17. The method according to claim 14,
wherein SiH₄ or Si₂H₆ gas is used as a reaction gas for the UHV-CVD method.

18. The method according to claim 14,
wherein a mixture of SiH₄ gas and GeH₄ gas is used as a reaction gas for the UHV-CVD method.

19. The method according to claim 14,
wherein a pressure of the UHV-CVD method is set to about 10 mTorr or less.

20. The method according to claim 14,
wherein an ALD method is used to form the high dielectric constant insulation film.

21. The semiconductor device according to claim 12,
wherein the metal dot comprises a compound including a metal component.
